(19) United States
(12) Patent Application Publication
(10) Pub. No.: US 2014/0231928 A1
(43) Pub. Date: Aug. 21, 2014

(54) Super Junction Semiconductor Device with an Edge Area Having a Reverse Blocking Capability

(71) Applicant: INFINEON TECHNOLOGIES AUSTRIA AG, Villach (AT)

(72) Inventors: Armin Willmeroth, Augsburg (DE); Franz Hirler, Isen (DE); Uwe Wahl, Munich (DE)

(73) Assignee: INFINEON TECHNOLOGIES AUSTRIA AG, Villach (AT)

(21) Appl. No.: 13/769,627

(22) Filed: Feb. 18, 2013

(51) Int. Cl. H01L 29/06; H01L 29/78

(52) U.S. Cl. CPC H01L 29/0603; H01L 29/78
USPC 257/409

(57) ABSTRACT

A semiconductor device includes a semiconductor layer with a super junction structure including first columns of a first conductivity type and second columns of a second conductivity type opposite the first conductivity type. The super junction structure is formed in a cell area and in an inner portion of an edge area surrounding the cell area. In the inner portion of the edge area a reverse blocking capability is locally reduced by a local modification of the semiconductor layer. The local modification allows an electric field to extend in case an avalanche breakdown occurs. The reverse blocking capability is locally reduced in the edge area, wherein once an avalanche breakdown has been triggered the semiconductor device accommodates a higher reverse voltage. Avalanche ruggedness is improved.

### BACKGROUND

A semiconductor portion of a super junction n-FET (field effect transistor) includes an n-type semiconductor layer with p-doped columns separated by n-doped columns. In the reverse mode depletion zones extend between the p-doped and n-doped columns in a lateral direction such that the n-FET accommodates a high reverse breakdown voltage at high impurity concentrations that provide a low on-state resistance. In an unclamped inductive switching environment FETs are used to switch off a current through an inductive load. The inductive load provokes an off-state current flowing through the FET until the energy stored in the inductive load has been dissipated. The induced current triggers an avalanche mechanism in the FET, wherein the electric field in the FET generates mobile charge carriers conveying the off-state current. Typical FET specifications specify a single-shot or repetitive avalanche ruggedness rating to enable the design of electric circuits with safe operating conditions. It is desirable to provide super junction semiconductor devices with improved avalanche ruggedness.

### SUMMARY

According to an embodiment a semiconductor device includes a semiconductor layer including a super junction structure with first columns of a first conductivity type and second columns of a second conductivity type opposite the first conductivity type. The super junction structure is formed in a cell area and in an inner portion of an edge area surrounding the cell area. In the inner portion a reverse blocking capability is locally reduced by a local modification of the semiconductor layer, wherein the local modification allows an electric field to extend in case an avalanche breakdown is triggered.

Those skilled in the art will recognize additional features and advantages upon reading the following detailed description and on viewing the accompanying drawings.

### BRIEF DESCRIPTION OF THE DRAWINGS

The accompanying drawings are included to provide a further understanding of the invention and are incorporated in and constitute a part of this specification. The drawings illustrate the embodiments of the present invention and together with the description serve to explain principles of the invention. Other embodiments of the invention and intended advantages will be readily appreciated as they become better understood by reference to the following detailed description.

FIG. 1A is a schematic cross-sectional view of a portion of a super junction semiconductor device in accordance with an embodiment providing an edge area with a locally modified field stop zone.

FIG. 1B is a schematic cross-sectional view of the portion of the super junction semiconductor device of FIG. 1A along line B-B.

FIG. 2 is a schematic cross-sectional view of a portion of a super junction semiconductor device with an edge area in accordance with an embodiment providing laterally tapered columns.

FIG. 3 is a schematic cross-sectional view of a portion of a super junction semiconductor device with an edge area in accordance with an embodiment providing a modification of a vertical extension of columns.

FIG. 4 is schematic cross-sectional view of a portion of a super junction semiconductor device with an edge area in accordance with an embodiment providing a modification of distances between columns.

FIG. 5 is a schematic cross-sectional view of a portion of a super junction semiconductor device with an edge area in accordance with an embodiment providing a local impurity modification.

### DETAILED DESCRIPTION

In the following detailed description, reference is made to the accompanying drawings, which form a part hereof, and in which are shown by way of illustrations specific embodiments in which the invention may be practiced. It is to be understood that other embodiments may be utilized and structural or logical changes may be made without departing from the scope of the present invention. For example, features illustrated or described for one embodiment can be used on or in conjunction with other embodiments to yield yet a further embodiment. It is intended that the present invention includes such modifications and variations. The examples are described using specific language which should not be construed as limiting the scope of the appending claims. The drawings are not scaled and are for illustrative purposes only. For clarity, the same elements have been designated by corresponding references in the different drawings if not stated otherwise.

The terms “having”, “containing”, “including”, “comprising” and the like are open and the terms indicate the presence of stated structures, elements or features but not preclude additional elements or features. The articles “a”, “an” and “the” are intended to include the plural as well as the singular, unless the context clearly indicates otherwise.

The term “electrically connected” describes a permanent low-ohmic connection between electrically connected elements, for example a direct contact between the concerned elements or a low-ohmic connection via a metal and/or highly doped semiconductor.

The Figures illustrate relative doping concentrations by indicating “−” or “+” next to the doping type “n” or “p”. For example, “n−” means a doping concentration which is lower than the doping concentration of an “n”-doping region while an “n+”-doping region has a higher doping concentration than an “n”-doping region. Doping regions of the same relative doping concentration do not necessarily have the same absolute doping concentration. For example, two different “n”-doping regions may have the same or different absolute doping concentrations.

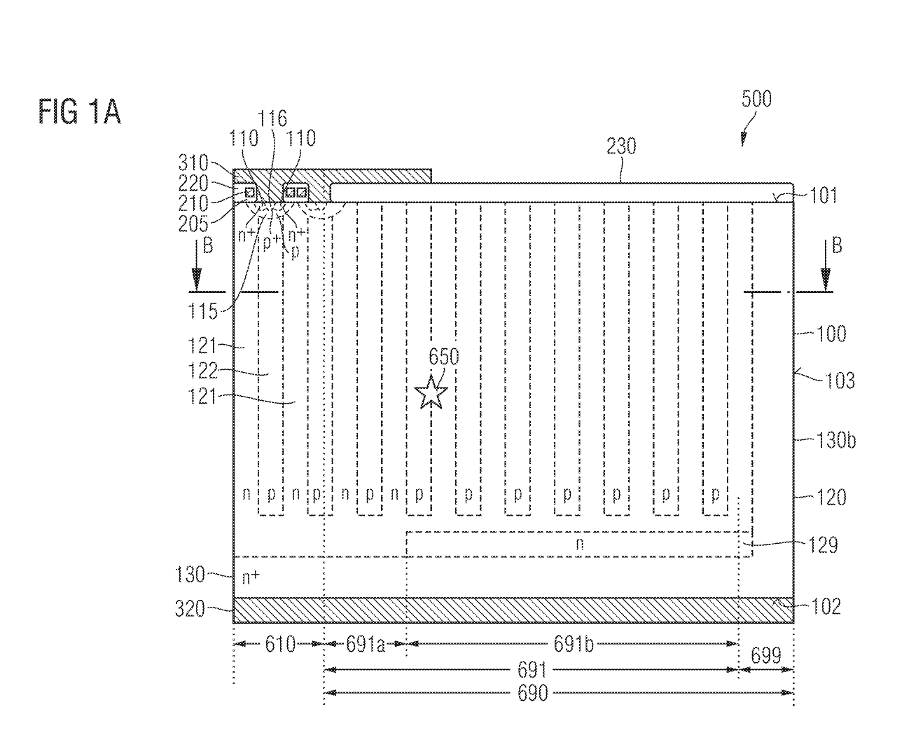

FIGS. 1A and 1B show a super junction semiconductor device 500 with a semiconductor portion 100 having a first surface 101 and a second surface 102 parallel to the first surface 101. The semiconductor portion 100 is provided from a single-crystalline semiconductor material, for example silicon Si, silicon carbide SiC, germanium Ge, a silicon germanium crystal SiGe, gallium nitride GaN or gallium arsenide GaAs. A distance between the first and second surfaces 101, 102 is at least 50 μm, for example at least 175 μm. The semiconductor portion 100 may have a rectangular shape with an edge length in the range of several millimeters. The normal to the first and second surfaces 101, 102 defines a vertical direction and directions orthogonal to the normal direction are lateral directions.

As shown in FIG. 1B, the semiconductor portion 100 includes a cell area 610 and an edge area 690 surrounding the cell area 610 in the lateral directions in an outermost section. The edge area 690 directly adjoins the cell area 610 and extends along an outer surface 103 of the semiconductor portion 100, wherein the outer surface 103 connects the first and second surfaces 101, 102. In a conductive state (on-state) of the semiconductor device 500 an on-state current flows between the first and second surfaces 101, 102 in the cell area 610. No or only a negligible portion of the on-state current flows in the edge area 690.

The semiconductor portion 100 may include an impurity layer 130 of a first conductivity type. The impurity layer 130 may extend along a complete cross-sectional plane of the semiconductor portion 100 parallel to the second surface 102. In case the semiconductor device 500 is an IGFET (insulated gate field effect transistor), the impurity layer 130 directly adjoins the second surface 102 and a mean net impurity concentration in the impurity layer 130 is comparatively high and may be at least 5×10¹⁸ cm⁻³, by way of example. In case the semiconductor device 500 is an IGBT (insulated gate bipolar transistor), a collector layer of a second conductivity type, which is the opposite of the first conductivity type, is arranged between the impurity layer 130 and the second surface 102 and a mean net impurity concentration in the impurity layer 130 is lower than 5×10¹⁸ cm⁻³.

Between the first surface 101 and the impurity layer 130 a semiconductor layer 120 includes a super junction structure with first columns 121 of the first conductivity type and second columns 122 of a second conductivity type that is the opposite of the first conductivity type. The second columns 122 may directly adjoin the impurity layer 130. According to other embodiments, the second columns 122 are formed at a distance to the impurity layer 130 such that the semiconductor layer 120 includes a continuous portion of the first conductivity type. The continuous portion extends between the buried edges of the first and second columns 121, 122 on the one hand and the impurity layer 130 on the other hand. The first and second columns 121, 122 directly adjoin to each other.

The first and second columns 121, 122 are provided in the cell area 610 and in an inner portion 691 of the edge area 690, wherein the inner portion 691 is oriented to the cell area 610. The first and second columns 121, 122 are absent in an outer portion 699 of the edge area 690 oriented to the outer surface 103. The outer portion 699 may include further termination structures, for example guard rings or a vertical field stop 130b of the first conductivity type formed along the outer surface 103.

The first and second columns 121, 122 may be parallel stripes arranged at regular distances. According to other embodiments, the cross-sectional areas of the second columns 122 parallel to the first surface 101 may be circles, ellipsoids, ovals or rectangles, e.g. squares, with or without rounded corners, and the first columns 121 are segments of a grid embedding the second columns 122. The first and second columns 121, 122 may extend from the cell area 610 into the edge area 690. Other first and second columns 121, 122 may be formed in the inner portion 691 of the edge area 690 exclusively.

The semiconductor portion 100 further includes source zones 110 of the first conductivity type and body zones 115 of the second conductivity type, wherein the body zones 115 are structurally and electrically connected to the second columns 122 and structurally separate the source zones 110 and the first columns 121.

The source zones 110 may be exclusively formed within the cell area 610 and may be absent in the edge area 690. The body zones 115 are provided at least in the cell area 610 and may or may not be absent in the edge area 690.

Gate dielectrics 205 electrically separate gate electrodes 210 and neighboring portions of the body zones 115. A potential applied to the gate electrodes 210 capacitively controls a minority charge carrier distribution in a portion of the body zones 115 adjoining the gate dielectrics 205 between the source zones 110 and the corresponding first columns 121 such that in an on-state of the semiconductor device 500 an on-state current flows between the source zones 110 and the impurity layer 130 through the body zones 115 and the semiconductor layer 120. The gate electrodes 210 may be exclusively formed in the cell area 610.

The gate electrodes 210 may be arranged above the first surface 101. According to other embodiments, the gate electrodes 210 may be buried in gate trenches extending from the first surface 101 into the semiconductor portion 100.

In the cell area 610, a first electrode structure 310 may be electrically connected to the source zones 110 and the body zones 115 through openings in a dielectric layer 220 covering the gate electrode structures 210. In the edge area 690 possibly provided source zones 110 are without low-ohmic connection to the first electrode structure 310.

The openings in the dielectric layer 220 are formed between neighboring gate electrodes 210. Heavily doped contact zones 116 of the second conductivity type may be formed within the body zones 115 in direct contact with the first electrode structure 310 to ensure a low-ohmic connection between the first electrode structure 310 and the body zones 115. The dielectric layer 220 electrically insulates the first electrode structure 310 from the gate electrodes 210.

A second electrode structure 320 directly adjoins the second surface 102 of the semiconductor portion 100. According to embodiments related to super junction IGFETs, the second electrode structure 320 directly adjoins the impurity layer 130. According to embodiments related to super junction IGBTs, a collector layer of the second conductivity type may be formed between the impurity layer 130 and the second electrode structure 320.

Each of the first and second electrode structures 310, 320 may consist of or contain, as main constituent(s) aluminum Al, copper Cu, or alloys of aluminum or copper, for example AlSi, AlCu or AlSiCu. According to other embodiments, one or both of the first and second electrode structures 310, 320 may contain, as main constituent(s), nickel Ni, titanium Ti, silver Ag, gold Au, platinum Pt and/or palladium Pd. For example, at least one of the first and second electrode structures 310, 320 includes two or more sub-layers, each sub-layer containing one or more of Ni, Ti, Ag, Au, Pt, and Pd as main constituent(s), e.g. silicides and/or alloys.

According to the illustrated embodiment, the first conductivity type is the n-type, the second conductivity type is the p-type, the first electrode structure 310 is a source electrode and the second electrode structure 320 is a drain electrode. According to other embodiments, the first conductivity type is the p-type.

In the inner portion 691 of the edge area 690 a reverse blocking capability is locally reduced by a local modification of the semiconductor layer 120. As a result, a significant portion of an avalanche breakdown takes place in a portion of the edge area 690 defined by the local modification as indicated by reference sign 650. Since in the edge area 690 the electric field has a certain field component in the lateral direction, the electric field has room to propagate in the avalanche case and the semiconductor device 500 can accommodate a higher voltage during the period in which it is in the avalanche mode. As a result, the inner portion 691 of the edge area 690 relieves the cell area 610 from thermal stress generated during the avalanche breakdown period and avalanche ruggedness is increased.

According to the embodiment of FIG. 1A, a local thickness variation of a field stop zone 129 provides the local modification in the edge area 690. The field stop zone 129 is formed between the super junction structure with the first and second columns 121, 122 and the drain layer 130 and is of the first conductivity type. The impurity concentration in the field stop zone 129 is at least two times the impurity concentration in the first columns 121 and at most half the impurity concentration in the impurity layer 130. For example, the impurity concentration in the field stop zone 129 is at least ten times the impurity concentration in the first columns 121 and at most a tenth the impurity concentration in the impurity layer 130.

In a first portion 691a of the inner portion 691 oriented to the cell area 610, the field stop zone 129 has a thickness that is lower than the thickness of the field stop zone 129 in a second portion 691b of the inner portion 691 oriented to the outer portion 699. For example, the field stop zone 129 may be completely absent in the first portion 691a. The local modification defines the location of an avalanche zone 650 where an avalanche breakdown is triggered at first mainly.

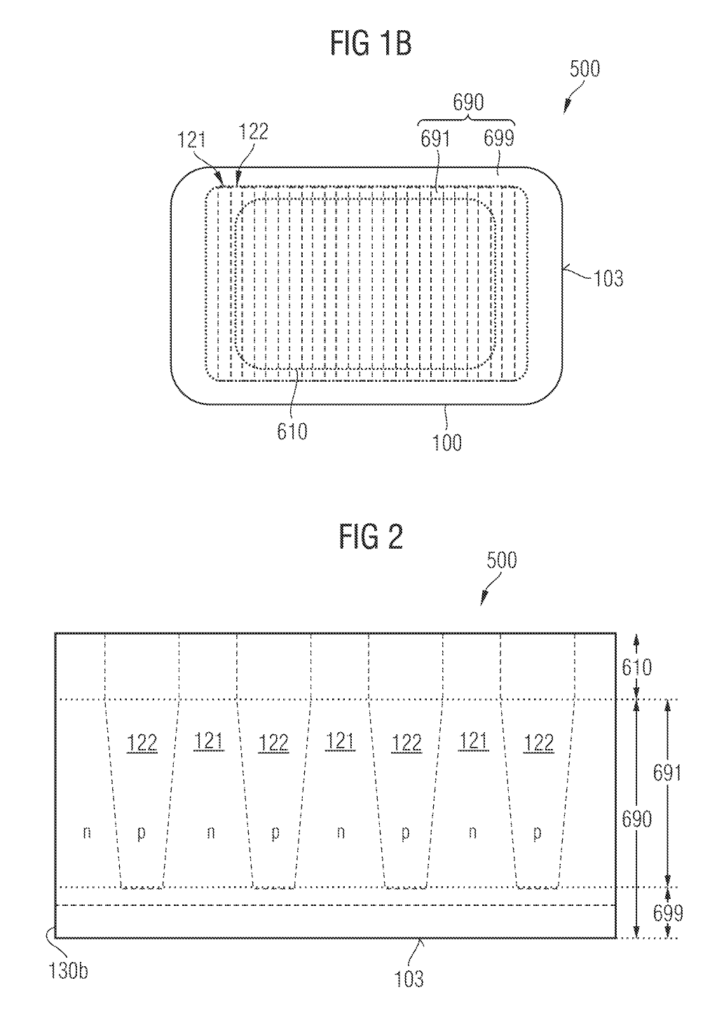

FIG. 2 refers to a local modification of both a lateral extension of the columns 121, 122 and a vertical extension of the second columns 122. The first and second columns 121, 122 are parallel stripes arranged at regular distances. In the inner portion 691 of the edge area 690 a width of the second columns 122 is reduced, such that the second columns 122 taper in direction of the outer surface 103. With the second columns 122 provided from a fill of vertical trenches etched from the first surface 101 into the semiconductor portion 100, the vertical extension of the second columns 122 decreases with decreasing distance to the outer surface 103. Accordingly, a degree of compensation (compensation rate) between the first and the second columns 121, 122 is shifted in direction of an n-load. As a result, the local reverse breakdown voltage decreases with decreasing distance to the outer surface 103 in the inner portion 691 of the edge area 690.

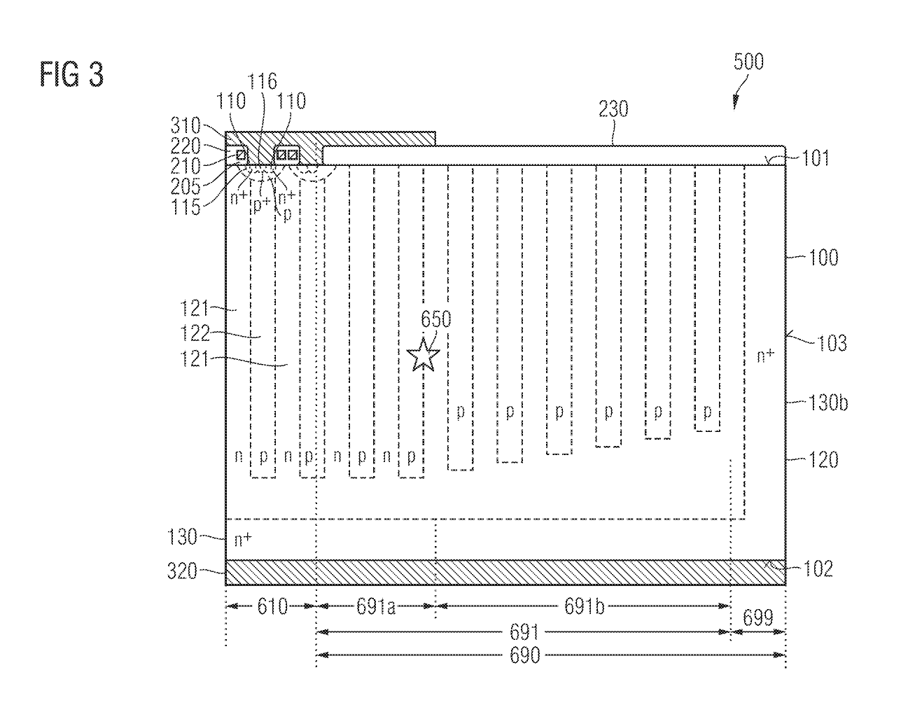

FIG. 3 shows an edge area 690 where a change of the vertical extension of the second columns 122 locally reduces the reverse blocking capability. In a first portion 691a of the inner portion 691 of the edge area 690, the second columns 122 have a first vertical extension. In a second portion 691b of the inner portion 691 of the edge area 690 the second columns 122 have second vertical extensions, which are different from the first vertical extension. According to an embodiment, all second columns 122 may have the same second vertical extension in the second portion 691b. Other embodiments may provide second columns 122 with steadily decreasing vertical extensions. Since in the edge area 690 the electric field vector has a component in a lateral direction, the electric field has more space to extend in the avalanche mode.

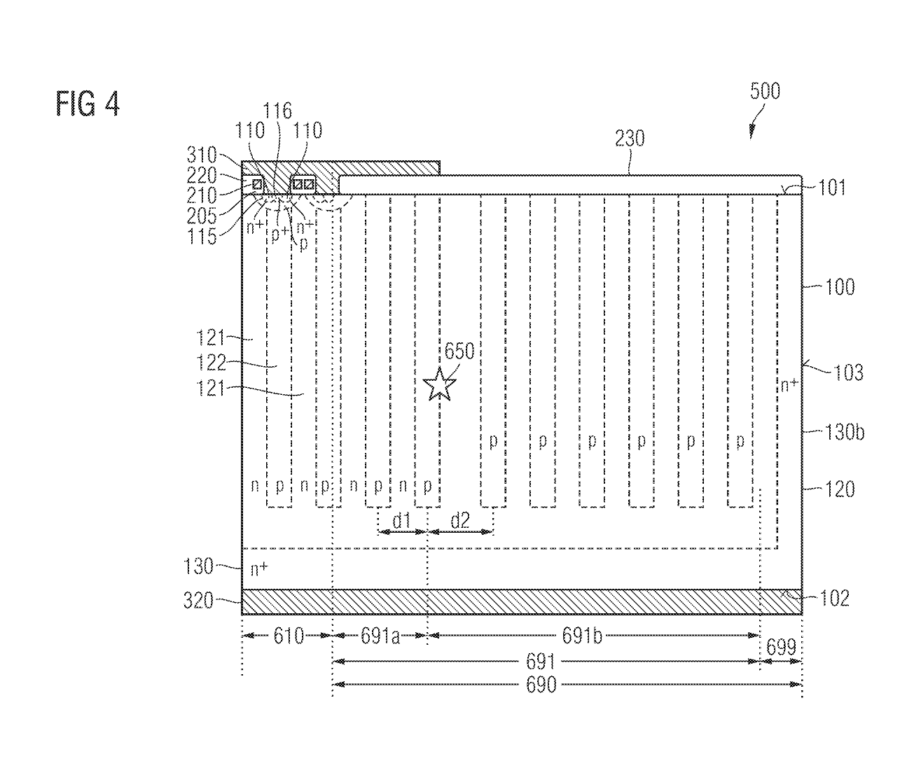

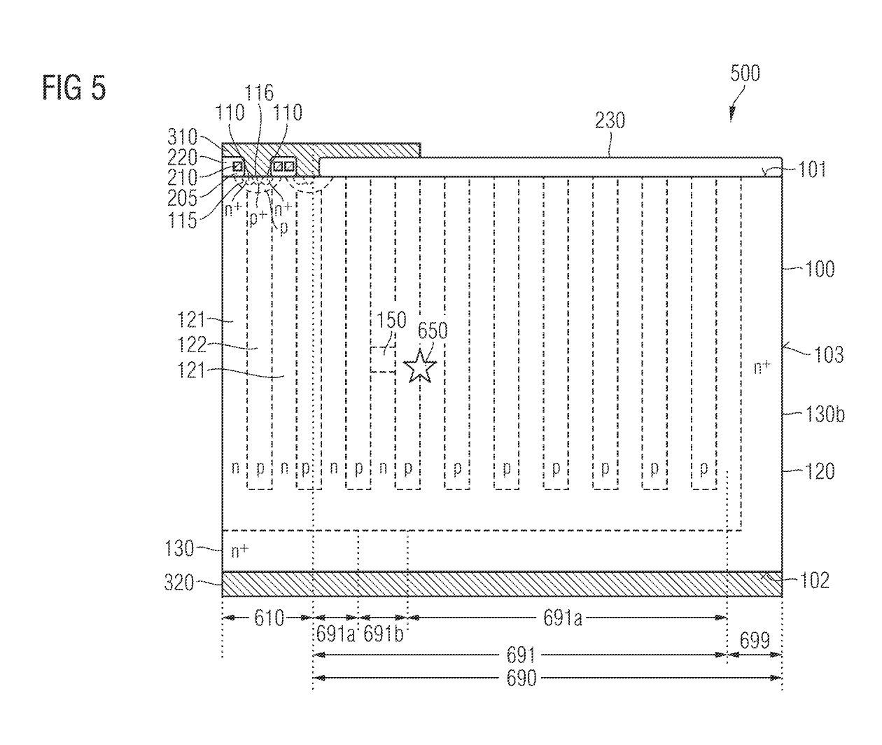

FIG. 4 refers to a local modification of the distance between two neighboring second columns 122. In a first portion 691a of the inner portion 691 of the edge area 690 neighboring second columns 122 have a first distance d1to each other and in a second portion 691b at least two of the second columns 122 have a second distance d2 to each other that is different from the first distance d1. According to other embodiments, the distances between neighboring second columns 122 may increase with decreasing distance to the outer surface 103.

Where FIGS. 2 to 4 achieve a suitable local modification of the semiconductor layer by a variation of a dimension of at least one of the columns, the embodiment of FIG. 5 provides the appropriate local modification by a variation of an impurity profile within at least one of the columns.

FIG. 5 shows an additional impurity zone 150 in a first portion 691a of an inner portion 691 of the edge area 690. The additional impurity zone 150 may be of the first conductivity type or the second conductivity type. The additional impurity zone 150 may be provided in a central section having approximately the same distance to the first end of the super junction structure oriented to the first surface 101 and to a second end of the super junction structure oriented to the second surface 102. According to an embodiment, the additional impurity zone 150 shifts the compensation to a load of the first conductivity type, for example an n-load. According to other embodiments, the additional impurity zone 150 may shift the compensation rate to a load of the second conductivity type, for example the p-load.

Though in the case an avalanche breakdown has been triggered, the edge area 690 does not accommodate the total avalanche current, the edge area 690 considerably reduces the avalanche current that must be accommodated by the cell area 610. In this way the edge area 690 relieves the cell area 610 from a thermal stress in the avalanche mode and further provisions for improving the avalanche ruggedness of the cell area 610 may become obsolete.

When the ratio between the edge area 690 and the cell area 610 is high, e.g. greater than 0.25, only low current densities have to be accommodated in the edge area 690 such that the edge area 690 can be effectively used for improving avalanche ruggedness.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor device, comprising:
a semiconductor layer comprising a super junction structure comprising first columns of a first conductivity type and second columns of a second conductivity type opposite the first conductivity type, the super junction structure formed in a cell area and in an inner portion of an edge area surrounding the cell area,
wherein in the inner portion of the edge area a reverse blocking capability is locally reduced by a local modification of the semiconductor layer allowing an electric field to extend in case an avalanche breakdown is triggered.

2. The semiconductor device according to claim 1, wherein the local modification is a variation of a dimension of at least one of the columns.

3. The semiconductor device according to claim 1, wherein the local modification is a variation of an impurity profile within at least one of the columns.

4. The semiconductor device according to claim 1, wherein the first and second columns extend in a vertical direction perpendicular to a first surface of a semiconductor portion including the semiconductor layer, the second columns separating neighboring first columns from each other.

5. The semiconductor device according to claim 1, wherein the local modification is a change of a vertical extension of a field stop zone provided in the semiconductor layer.

6. The semiconductor device according to claim 5, wherein in the inner portion of the edge area a first portion of the field stop zone has a first vertical extension and a second portion of the field stop zone has a second vertical extension different from the first vertical extension.

7. The semiconductor device according to claim 5, wherein the field stop zone is of the first conductivity type and directly adjoins an impurity layer formed between the semiconductor layer and a second surface of a semiconductor portion including the semiconductor layer and the impurity layer.

8. The semiconductor device according to claim 1, wherein the local modification is a change of a vertical extension of at least one of the second columns along a direction perpendicular to a first surface of a semiconductor portion including the semiconductor layer.

9. The semiconductor device according to claim 8, wherein the at least one second column has a first vertical extension and the remaining second columns have second vertical extensions different from the first vertical extension.

10. The semiconductor device according to claim 1, wherein the local modification is a change of a lateral extension of at least one of the second columns along a lateral direction parallel to a first surface of a semiconductor portion including the semiconductor layer.

11. The semiconductor device according to claim 1, wherein the first and second columns are stripes extending along a first lateral direction and the local modification is a change of a stripe length of at least one of the second columns.

12. The semiconductor device according to claim 1, wherein the first and second columns are rectangular stripes extending along a first lateral direction and the local modification is a change of a stripe width of the second columns.

13. The semiconductor device according to claim 12, wherein at least one of the second columns has a first width and the remaining second columns have second widths different from the first width.

14. The semiconductor device according to claim 1, wherein the first and second columns are stripes extending along a first lateral direction and the local modification is a change of a stripe width of at least one of the second columns.

15. The semiconductor device according to claim 14, wherein the local modification is a tapering of the at least one second column.

16. The semiconductor device according to claim 1, wherein the local modification is a change of a net mean impurity concentration in one of the first and second columns.

17. The semiconductor device according to claim 16, further comprising:
at least one additional impurity zone provided in a central section between an end of the super junction structure oriented to a first surface of a semiconductor portion including the semiconductor layer and an opposite end of the super junction structure oriented to a second surface parallel to the first surface.

18. The semiconductor device according to claim 17, wherein the at least one additional impurity zone is assigned to either the first or the second columns.

19. The semiconductor device according to claim 1, further comprising:
body zones of the second conductivity type, each body zone being structurally connected with one of the second columns;
source zones of the first conductivity type, each source zone being embedded in one of the body zones; and
a first electrode structure electrically connected with the source zones in a cell area.

20. The semiconductor device according to claim 19, wherein the source zones are absent or not electrically connected to the first electrode structure in the edge area.

21. The semiconductor device according to claim 1, wherein an on-state current flows between two opposing surfaces of a semiconductor portion including the semiconductor layer in the cell area and does not flow in the edge area.

22. The semiconductor device according to claim 1, wherein the super junction structure is absent in an outer portion of the edge area.
